(19) United States
(12) Patent Application Publication
(10) Pub. No.: US 2026/0309549 A1
(43) Pub. Date: Oct. 8, 2026

(54) ARCHITECTURE OF AN ABSORPTION ZONE FOR AN INFRARED DETECTOR

(71) Applicants: COMMISSARIAT A L'ENERGIE ATOMIQUE ET AUX ENERGIES ALTERANATIVES, PARIS (FR); LYNRED, PALAISEAU (FR)

(72) Inventors: Axel EVIRGEN, PALAISEAU (FR); Bruno GERARD, PALAISEAU (FR)

(21) Appl. No.: 19/478,798

(22) PCT Filed: Apr. 24, 2024
(86) PCT No.: PCT/EP2024/061202

§ 371 Date: Oct. 24, 2025

(30) Foreign Application Priority Data
Apr. 27, 2023 (FR) FR2304271

(51) Int. Cl. G01J 5/08; G01J 5/20; H10F 39/18; H10F 77/14

(52) U.S. Cl. CPC G01J 5/0853; G01J 5/20; H10F 39/184; H10F 77/146

(57) ABSTRACT

A detection device configured to detect infrared radiation at a predetermined operating temperature, includes at least one pixel formed by a stack of layers on a substrate in the first direction normal to the substrate, the pixel including an absorption heterostructure includes at least: a first planar absorption structure having a first maximum valence band value, and a second planar absorption structure adjacent to the first planar absorption structure. The second planar absorption structure has a second maximum valence band value distinct from the first maximum valence band value. The thickness of each of the first and second planar absorption structures being selected so as to create at least one interface electric field at the interface between the second planar absorption structure and the first planar absorption structure. The interface electric field is oriented in the first direction.

### CROSS-REFERENCE TO RELATED APPLICATIONS

This application is a National Stage of International patent application PCT/EP2024/061202, filed on Apr. 24, 2024, which claims priority to foreign French patent application No. FR 2304271, filed on Apr. 27, 2023, the disclosures of which are incorporated by reference in their entireties.

### FIELD OF THE INVENTION

The present invention relates to the field of infrared (IR) imaging and in particular to a radiation detector or a photodetector manufactured with heterostructures based on III-V type semiconductor materials. More specifically, the invention relates to an imaging device operating in long-wave infrared (LWIR), mid-wave infrared (MWIR) and short-wave infrared (SWIR).

### BACKGROUND

Imagers operating in the infrared range are generally formed by assembling a matrix comprising a plurality of elementary pixels based on photodiodes converting a flux of incident photons into photo-generated charge carriers, and a read circuit commonly referred to as ROIC for “Read Out Integrated Circuit” for processing the electrical signal originating from the pixels of the detector.

The invention proposes solving a technical problem in this field consisting in designing a matrix detector operating in the infrared range at cryogenic temperatures for MWIR and LWIR and non-cryogenic temperatures for SWIR by reducing the cross-talk phenomenon between the pixels of the matrix to a pitch of less than 15 μm, without increasing the dark current noise compared to the solutions of the prior art.

Initially, a physical explanation will be provided of these two interdependent features of an infrared matrix sensor.

By way of illustration, in a space (X, Y, Z) the axis Δ of each pixel is defined in the direction Z, and the plane with the axis of the pixel as the normal, called normal plane, is the plane (X, Y).

Each infrared matrix detector is characterized by a cut-off wavelength Ac defined by the effective energy gap Eg_{eff} of the absorbing zone of each pixel of the matrix detector according to the Planck-Einstein relation λc=HC/Eg_{eff}, with h being the Planck constant et c being the speed of light in a vacuum. The cut-off length then depends on the energy band structure of the materials used to produce the absorbing zone of the pixel.

The cross-talk phenomenon originates from the interference between adjacent pixels, with the photo charges generated by a pixel being able to diffuse towards a neighbouring pixel along the plane with the axis of the pixel as the normal. The amplitude of the cross-talk phenomenon in an infrared matrix detector increases with the diffusion length, denoted L_{dx,y}, of the minority charge carriers in the normal plane (X, Y). The diffusion length L_{dx,y} in the plane normal to the pixel increases with the diffusion coefficient in the same plane. The diffusion coefficient is inversely proportional to the effective masses mₕₓ and m_{hy} of the minority charge carriers (holes in the case of an N-doped absorbing zone) in the plane normal to the pixel. The cross-talk phenomenon constitutes a technical limitation for the correct operation of pixel matrices with a reduced pitch, notably of less than 15 μm.

For example, for a detector in the mid-wave infrared range, the diffusion length is generally greater than 15 μm. Thus, for a pixel pitch of less than 15 μm, the resolution of the imager is degraded relative to the theoretical resolution it can reach. In order to quantify this degradation, the modulation transfer function (MTF) is measured at the Nyquist frequency. The value obtained for the solutions of the prior art is less than 0.5 compared to a theoretical value of 0.64.

The dark current J_{dark} is the current of charge carriers generated in the absence of incident radiation in the materials that make up the absorbing zone of a pixel of the detection matrix. The dark current can be expressed using the following formula:

$${J}_{dark} = \frac{{n}_{i}^{2}}{τ N} d$$

Where nᵢ is the intrinsic charge carrier density in the absorption zone, τ is the lifetime of the minority charge carriers, N is the doping and d is the thickness of the absorption zone. N and d are dimensional parameters, τ depends on the manufacturing conditions.

In summary, the technical challenge is to find a solution for limiting the degradation of the resolution with the reduction of the pixel pitch because of the increase in cross-talk, without increasing the dark current and to do so for a given cut-off frequency at a given operating temperature.

The technical problem to be solved is then to develop infrared detectors with pixels comprising absorbing zones with an improvement of the following interdependent criteria: maximizing the modulation transfer function (MTF) of a detection system and simultaneously minimizing cross-talk and dark current noise constraints at a given cut-off frequency, a given pixel pitch and a given operating temperature.

### Prior Art/Limitations of the Prior Art

The publication “Large format InSb infrared detector with 10 μm pixels”, by Gershon et al., sets forth an infrared detector with a pixel matrix with a pixel pitch of 15 μm and of 10 μm at 150 K. The solution that is described has a modulation transfer function of less than 0.45 for a pitch of 15 μm and of less than 0.35 for a pitch of 10 μm. This reflects a degradation in the performance of the detector due to the increase in cross-talk effects between adjacent pixels.

### Response to the Problem and Provision of a Solution

In order to overcome the limitations of existing solutions in terms of improving resolution while minimizing cross-talk and dark current, the invention proposes several embodiments of a pixel structure comprising an absorption heterostructure with at least two adjacent planar structures with close energy gaps and offset valence and/or conduction band levels. This energy band offset allows a local electric field to be created at the interface between the two adjacent planar structures. The local electric field is oriented along the axis of the pixel, the axis Δ, so as to channel the charge carriers in the axial direction of the pixel. This allows the transport of the charge carriers along the plane (X, Y) to be reduced and thus limits the cross-talk phenomenon. The offset between the valence (and/or conduction) band levels is less than 4 kT, with k being the Boltzmann constant and τ being the predetermined operating temperature. This allows a flat energy band structure to be maintained in the planar heterostructure and thus avoids any increase in the dark current by the appearance of a space charge zone devoid of charge carriers.

Advantageously, the absorption heterostructure comprises a repetitive alternation of the adjacent planar structures according to the invention in order to improve the channelling of the charge carriers along the axis of the pixel.

Advantageously, the absorption heterostructure comprises a succession of several absorption structures with different materials according to the invention, so as to form a descending stepped energy diagram in the axial direction of the pixel.

The adjacent planar absorption structures according to the invention can be made of a superlattice or of a solid material. The invention describes embodiments with examples of choices of materials for the planar absorption structures, ranges for the compositions of the semiconductor alloys and ranges for the dimensioning of the thicknesses of the layers of the absorption heterostructure according to the invention. The compositions (molar fractions of III-V alloys) of the materials used to produce the layers of the absorption heterostructure according to the invention are selected so as to obtain the energy band diagram according to the invention. This makes it possible to improve, at the same time, compared to the solutions of the prior art, the performance of the IR detector in terms of quantum efficiency, dark current reduction and cross-talk reduction.

### SUMMARY OF THE INVENTION

The subject of the invention is a detection device configured to detect infrared radiation at a predetermined operating temperature, comprising at least one pixel formed by a stack of layers on a substrate in the first direction normal to said substrate, said pixel comprising an absorption heterostructure, said absorption heterostructure comprising at least:
a first planar absorption structure having a first maximum valence band value;
and a second planar absorption structure adjacent to the first planar absorption structure;
   said second planar absorption structure having a second maximum valence band value distinct from the first maximum valence band value; the thickness of each of the first and second planar absorption structures being selected so as to create at least one interface electric field at the interface between the second planar absorption structure and the first planar absorption structure, said interface electric field being oriented in said first direction.

According to a particular aspect of the invention, the difference between the first maximum valence band value and the second maximum valence band value is less than four times the product of the Boltzmann constant and the operating temperature.

According to a particular aspect of the invention, the thickness of each of the first and second planar absorption structures is greater than or equal to 20 nm.

According to a particular aspect of the invention, the first planar absorption structure has a first energy gap and the second planar absorption structure has a second energy gap, with the absolute difference between the first energy gap and the second energy gap being less than or equal to 20 meV.

According to a particular aspect of the invention, the first planar absorption structure has a first minimum conduction band value and the second planar absorption structure has a second minimum conduction band value distinct from the first minimum conduction band value with an energy difference of less than four times the product of the Boltzmann constant and the operating temperature.

According to a particular aspect of the invention, the absorption heterostructure comprises a periodic alternation of the first planar absorption structure and the second planar absorption structure.

According to a particular aspect of the invention, the absorption heterostructure is doped with N- or P-type dopants, with the concentration of said dopants being asymmetrical on either side of at least one interface between a first planar absorption structure and a second planar absorption structure.

According to a particular aspect of the invention, the absorption heterostructure is doped with N- or P-type dopants, with the concentration of said dopants having a decreasing gradient from the interface with the lower electrode to the interface with the upper electrode.

According to a particular aspect of the invention, the absorption zone comprises a stack of a succession of several planar absorption structures of rank i=1 to N increasing from the substrate in the first direction, with N being a natural integer strictly greater than 1, such that:
each planar absorption structure of rank i=1 to N-1 has a maximum valence band value that is strictly greater than the maximum valence band value of the planar absorption structure of rank i+1, so as to create at least one interface electric field directed in the first direction at each interface,
   with said succession of several planar absorption structures comprising the assembly formed by the first planar absorption structure and the second planar absorption structure.

According to a particular aspect of the invention, the difference between, on the one hand, the maximum valence band value of a planar absorption structure of rank i=1 to N-1 and, on the other hand, the maximum valence band value of an adjacent planar absorption structure of rank i+1 is less than four times the product of the Boltzmann constant and the operating temperature.

According to a particular aspect of the invention, the absolute difference between the energy gaps associated with two adjacent planar absorption structures is less than or equal to 20 meV.

According to a particular aspect of the invention, each planar absorption structure is made of III-V type semiconductor materials.

According to a particular aspect of the invention, the substrate is made of GaSb or InAs or InP or GaAs.

According to a particular aspect of the invention, the first planar absorption structure is produced by a first solid layer made of a first material or a first superlattice and the second planar absorption structure is produced by a second solid layer made of a second material different from said first material or a second superlattice.

According to a particular aspect of the invention, the first material is InAs_{1-y}Sb_{y} alloy or Ga₁₋ₓInₓAs alloy or GaₓIn₁₋ₓAs_{1-y}Sb_{y} alloy or GaₓIn₁₋ₓAs_{1-y}P_{y} alloy.

According to a particular aspect of the invention, the second material is GaₓIn₁₋ₓAs_{1-y}Sb_{y} alloy or Ga₁₋ₓInₓAs alloy or GaₓIn₁₋ₓAs_{1-y}P_{y} alloy.

According to a particular aspect of the invention, the first superlattice and/or the second superlattice is formed by an alternation in accordance with a predetermined spatial period of a pair of layers of InAs_{1-y}Sb_{y}/GaₓIn₁₋ₓAs_{1-y}Sb_{y} or of InₓGa₁₋ₓAs/InₓGa₁₋ₓAs_{1-y}P_{y} or of Inₓ₁Ga₁₋ₓ₁As_{1-y1}Sb_{y1}/Inₓ₂Ga₁₋ₓ₂As_{1-y2}Sb_{y2}.

According to a particular aspect of the invention, the detection device further comprises a matrix of pixels having a pixel pitch that is less than or equal to 15 μm.

### BRIEF DESCRIPTION OF THE DRAWINGS

Within the scope of the description of the invention, the term “planar absorption structure” defines a layer made of a solid material or a stack of layers forming a superlattice capable of converting an incident ray into charge carriers.

Further features and advantages of the present invention will become more clearly apparent upon reading the following description, with reference to the following appended drawings.

FIG. 1 illustrates a perspective view of an example of a pixel belonging to a matrix detector in the infrared frequency range.

FIG. 2a illustrates a sectional view of an infrared detector pixel comprising an absorption heterostructure according to a first embodiment of the invention.

FIG. 2b illustrates a diagram of the structure of the bands of the absorption heterostructure according to the first embodiment of the invention in the direction of the axis of the pixel.

FIG. 2c illustrates the distribution of the electric field in the absorption heterostructure according to the first embodiment of the invention in the direction of the axis of the pixel.

FIG. 3a illustrates a sectional view of an infrared detector pixel comprising an absorption heterostructure according to a second embodiment of the invention.

FIG. 3b illustrates the distribution of the electric field in the absorption heterostructure according to the second embodiment of the invention in the direction of the axis of the pixel.

FIG. 4 illustrates a sectional view of an infrared detector pixel comprising an absorption heterostructure according to a third embodiment of the invention.

FIG. 5a illustrates a sectional view of an infrared detector pixel comprising an absorption heterostructure according to a fourth embodiment of the invention.

FIG. 5b illustrates a diagram of the structure of the bands of the absorption heterostructure according to the fourth embodiment of the invention in the direction of the axis of the pixel.

FIG. 5c illustrates the distribution of the electric field in the absorption heterostructure according to the fourth embodiment of the invention in the direction of the axis of the pixel.

### DETAILED DESCRIPTION

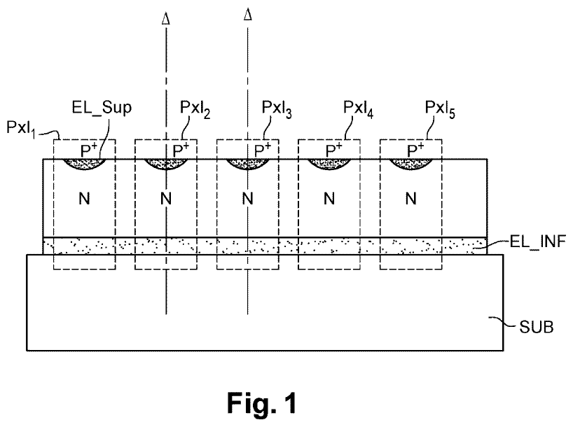

FIG. 1 illustrates a perspective view of an example of several adjacent pixels belonging to a matrix detector D1 in the infrared frequency range.

The illustration is limited to a single row of pixels Pxl₁ to Pxl₅ for the sake of simplification, but it does not exclude the integration of pixels in a matrix comprising a plurality of rows and columns of pixels.

A pixel Pxlᵢ (i=1 to 5) of the infrared detector is formed by a stack of layers of semiconductor materials forming the structure of the pixel on a substrate SUB. The pixel axis Δ is the axis perpendicular to the horizontal plane (x, y) formed by the upper surface of the substrate SUB. The substrate SUB is made of a solid semiconductor material of the III-V type, for example. The selection of the material of the substrate SUB is important because it determines the technology of the steps of the method for manufacturing the device, but also the technical features (optical, electrical, mechanical, etc.) of the matrix detector. The pixel Pxlᵢ comprises the following layers (or multilayers), starting from the substrate, in the direction of the axis of the pixel A: a lower electrode EL_INF, an absorption zone SPA and an upper electrode EL_SUP.

The lower electrode EL_INF is confined between the absorption zone SPA and the substrate SUB. The lower electrode EL_INF can be made of solid semiconductor material or of N+ doped superlattice material. Preferably, the material forming the lower electrode EL_INF is of the III-V type, such as, by way of example, gallium arsenide, indium arsenide, gallium nitride, gallium antimonide, indium antimonide, indium phosphide, boron phosphide, as well as their ternary, quaternary or quinary alloys. The lower electrode EL_INF can also be made with heterostructures obtained by stacking a plurality of thin layers of N, N+ doped solid semiconductor or superlattice materials, preferably of the III-V type, such as, by way of example, gallium arsenide, indium arsenide, gallium nitride, gallium antimonide, indium antimonide, indium phosphide, boron phosphide, and their ternary or quaternary or quinary alloys. Alternatively, the lower electrode EL_INF forms, by way of example, an N+ doped superlattice with a large energy gap value relative to the absorption zone SPA.

The absorption zone SPA is formed by a stack of N-doped layers and has an energy gap value that is less than or equal to that of the upper electrode. The features of the band diagram of the absorption zone SPA (valence band, conduction band, energy gap) are intrinsic in the case of a solid material, or effective resulting from the combination of the various thin layers in the case of a superlattice. Within the scope of the description of the invention, the term “effective” has been omitted for superlattices in order to simplify the description.

The absorption zone SPA converts the flux of incident photons with a wavelength A into negative charge carriers, “electrons”, in the conduction band and into positive charge carriers, “holes”, in the valence band of the absorption zone SPA. For the devices that are the focus of the invention, this involves a photoelectric effect where the minority charge carriers (the holes for N doping) are used to generate the reading signal following stimulation by infrared radiation. The semiconductor materials used to produce the absorption zone SPA (in the form of solid material or a superlattice) can be of the III-V type, such as, by way of example, gallium arsenide, indium arsenide, gallium nitride, gallium antimonide, indium antimonide, indium phosphide, boron phosphide, and their ternary or quaternary or quinary alloys. The structure of the energy bands in the absorption zone SPA is decisive for increasing the cut-off frequency of the matrix detector comprising the pixel Pxlᵢ. In the illustrated example, the absorption zone SPA is N-doped.

The upper electrode EL_SUP is produced, by way of non-limiting example, by a P+ doping zone at the upper face of the absorption zone SPA. Alternatively, the upper electrode EL_SUP can be made of materials generally having a large energy gap value relative to the absorption zone SPA. These materials are preferably of the Ill-V type, such as, by way of example, gallium arsenide, indium arsenide, gallium nitride, gallium antimonide, indium antimonide, indium phosphide, boron phosphide, as well as their ternary, quaternary or quinary alloys. The upper electrode EL_SUP also can be made with heterostructures obtained by stacking a plurality of thin layers of semiconductor materials preferably of the III-V type, such as, by way of example, gallium arsenide, indium arsenide, gallium nitride, gallium antimonide, indium antimonide, indium phosphide, boron phosphide, and their ternary or quaternary or quinary alloys. The upper electrode EL_SUP forms, by way of example, a P+ doped superlattice with a large energy gap value relative to the absorption zone SPA. The upper electrode EL_SUP is intended to collect the charges generated by the absorption zone SPA.

The different doping between the upper electrode EL_SUP and the absorption zone means that the migration direction of the photo-generated positive charges is from the lower electrode EL_INF towards the upper electrode EL_SUP.

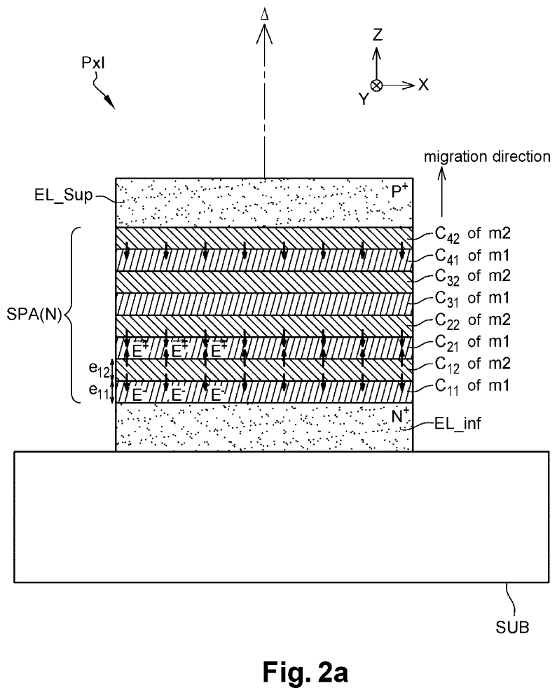

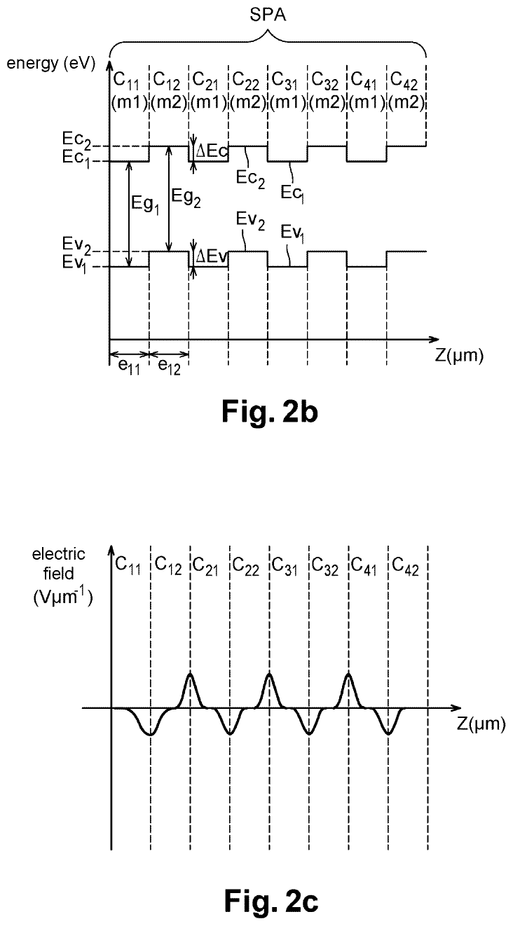

FIG. 2a illustrates a sectional view of an infrared detector pixel Pxl comprising an absorption heterostructure SPA according to a first embodiment of the invention.

The absorption zone SPA is a heterostructure obtained by stacking in the axial direction Z. The absorption heterostructure SPA comprises N planar absorption structures (C₁₁, C₂₁, C₃₁ etc.) corresponding to solid layers made of a first material m1, with N being a non-zero natural integer. The absorption heterostructure SPA further comprises N planar absorption structures (C₁₂, C₂₂, C₃₂ etc.) corresponding to solid layers of a second material m2, with N being a non-zero natural integer. The planar structures are alternately stacked so as to obtain a heterostructure formed by adjacent solid layers of different materials m1 and m2. The first material m1 is a semiconductor characterized by a first maximum valence band value Ev₁, a first minimum conduction band value Ec₁, and a first energy gap value E_{g1}. The second material m2 is a semiconductor characterized by a second maximum valence band value Ev₂, a second minimum conduction band value Ec₂, and a second energy gap value Eg₂. The second maximum valence band value Ev₂ is distinct from the first maximum valence band value Ev₁ with an energy difference (also called offset) of less than 4·K_{b}T, with K_{b} being the Boltzmann constant and τ being the operating temperature of the detector. The level offset of the valence bands induces the creation of a local electric field E at each interface between a planar absorption structure of the first material m1 and a planar absorption structure of the second material m2. The interface electric field E at each interface has a direction parallel to the direction Z of the axis Δ of the pixel. This allows the movement of photogenerated charge carriers to be channeled along the axis of the pixel and thus reduces the diffusion of charge carriers along the normal plane (X, Y) towards adjacent pixels. This results in a reduction in the cross-talk phenomenon between pixels to reduced pixel pitch values.

The first material m1 and the second material m2 are semiconductor materials, preferably of the III-V type.

The first and second energy gap values Eg₁ and Eg₂ are close to each other, with an absolute difference of less than 20 meV. This allows an absorption heterostructure SPA to be obtained that is capable of converting radiation to the operating wavelength. Advantageously, the first and second energy gap values Eg₁ and Eg₂ are equal.

Advantageously, the second minimum conduction band value Ec₂ is distinct from the first minimum conduction band value Ec₁ with an energy difference (also called offset) of less than 4·K_{b}T, with K_{b} being the Boltzmann constant and τ being the operating temperature of the detector.

Limiting offsets between the valence (and conduction) energy bands to 4K_{b}T allows a practically planar band configuration to be maintained for the energy potential in the absorption zone. Thus, the creation of space charge zones devoid of charge carriers conducive to the creation of a strong generation-recombination current in the absorption heterostructure SPA according to the invention is avoided. This results in a reduction in the cross-talk phenomenon without increasing the dark current.

In the illustrated example, the number of repetitions N is equal to 4 by way of non-limiting indication. The technical effect relating to the invention is obtained from N=1, with a first planar absorption structure C₁₁ and a second planar absorption structure C₁₂. The absorption heterostructure SPA comprises at least one first planar absorption structure C₁₁ and one second planar absorption structure C₁₂ with the aforementioned band diagram features. The first planar absorption structure C₁₁ and the second planar absorption structure C₁₂ are adjacent. The interface formed between the two planar structures has a potential difference that induces an electric field E with a direction parallel to that of the axis Δ of the pixel Pxl.

A first planar absorption structure C₁₁ made of the first material m1 and of rank i has a thickness eᵢ₁ in the direction Z. A second planar absorption structure Cᵢ₂ made of the second material m2 and of rank i has a thickness eᵢ₂ in the direction Z. The thickness eᵢ₁ (and eᵢ₂) of each of the planar absorption structures Cᵢ₁ (and Cᵢ₂) is greater than or equal to 20 nm. Indeed, the alternating stack forming the absorption heterostructure SPA is not a superlattice or a multiple quantum well. A superlattice and a quantum well are defined by way of a reminder: In semiconductor physics, a superlattice is a periodic stack of layers with a minimal thickness of a few nanometres. If these layers are thin enough (generally less than 10 nm), quantum coupling is possible. The carriers (holes and electrons) then have access to an energy continuum according to “mini-bands”. In the case of a quantum well, the layer with the material exhibiting the minimum of the lowest energy conduction band and/or the maximum of the highest energy valence band is less than 20 nm thick, with the one or more other layers being more than 20 nm thick. In this case, the charge carriers reach discrete energy levels along the axis of the period. The thicknesses eᵢ₁ and eᵢ₂ are selected so to avoid quantum coupling between the superposed layers and thus remain in an energy band structure.

FIG. 2b illustrates the structure of the bands of the absorption heterostructure SPA in the direction of the axis of the pixel Pxl of FIG. 2a. An alternating band structure can be seen with variations in valence levels ΔEv and variations in conduction levels ΔEc corresponding to the interfaces between adjacent layers of different materials. By way of example, when positive charge carriers are collected for detection, the variations in valence levels ΔEv experienced by the holes correspond to interface electric fields along the axis of the pixel. This results in the charges being channeled along the axis Δ. This allows the cross-talk phenomenon to be reduced.

The migration direction of the photogenerated charge carriers is directed from the lower electrode EL_INF towards the upper electrode EL_SUP through the absorption heterostructure SPA. On the one hand, during the transition from a planar structure made of said first material m1 (C₁₁, C₂₁, C₃₁ etc.) to a planar structure made of said second material m2 (C₁₂, C₂₂, C₃₂ etc.), the interface electric field E vector is directed in a direction opposite the migration direction. In this case, the interface electric field E is considered to be negative. On the other hand, during the transition from a planar structure made of said second material m2 to a planar structure made of said first material m1, the interface electric field E is directed in the migration direction. In this case, the interface electric field E is considered to be positive. FIG. 2c illustrates the distribution of the electric field in the absorption heterostructure SPA in the direction of the axis of the pixel. The alternation between negative and positive interface electric fields E is illustrated by this diagram. The negative interface electric fields E slow down the movement of the charge carriers towards the upper electrode EL_SUP and the positive interface electric fields E accelerate the movement of the charge carriers toward the upper electrode EL_SUP. However, despite the opposing effect of said negative interface electric fields E, the photogenerated charges still propagate towards the upper electrode EL_SUP under the overall effect of the band structure.

In the case in which the absorption heterostructure SPA is made up of two planar structures C₁₁ and C₁₂, such that the first planar structure C₁₁ is deposited on the lower electrode EL_INF and the second planar structure C₁₂ is deposited on said first planar structure C₁₁. The first planar structure C₁₁ has a first maximum valence band value Ev₁ that is greater than the maximum valence band value Ev₂ of the second planar structure C₁₂ with an energy difference (also called offset) of less than 4·K_{b}T, with K_{b} being the Boltzmann constant and τ being the operating temperature of the detector. This allows a positive interface electric field E to be created.

By way of non-limiting example of the first embodiment of the invention, the substrate SUB is made of GaSb; the first material m1 is InAs_{1-y1}Sb_{y1} alloy, with y1 being the molar fraction of Sb in the InAs_{1-y1}Sb_{y1} alloy, such that 0.05≤y1≤0.15; the second material m2 is Gaₓ₂ In₁₋ₓ₂As_{1-y2}Sb_{y2} alloy, with x2 being the molar fraction of Ga in the Gaₓ₂In₁₋ₓ₂As_{1-y2}Sb_{y2} alloy, such that 0≤x2≤0.5 and y2 being the molar fraction of Sb in the Gaₓ₂In₁₋ₓ₂As_{1-y2}Sb_{y2} alloy, such that y2=0.914.x2+z, with 0.05≤z≤0.15. The absorption heterostructure SPA is achieved by epitaxial growth on the substrate SUB.

By way of non-limiting example of the first embodiment of the invention, the substrate SUB is made of InAs; the first material m1 is InAs_{1-y3}Sb_{y3} alloy, with y3 being the molar fraction of Sb in the InAs_{1-y3}Sb_{y3} alloy, such that 0≤y3≤0.07; the second material m2 is Gaₓ₄In₁₋ₓ₄As_{1-y4}Sb_{y4} alloy, with x4 being the molar fraction of Ga in the Gaₓ₄In₁₋ₓ₄As_{1-y4}Sb_{y4} alloy, such that 0≤x4≤0.5 and y4 being the molar fraction of Sb in the Gaₓ₄In₁₋ₓ₄As_{1-y4}Sb_{y4} alloy, such that y1=0.914.x1+z, with 0≤z≤0.07. The absorption heterostructure SPA is achieved by epitaxial growth on the substrate SUB.

By way of non-limiting example of the first embodiment of the invention, the substrate SUB is made of InP; the first material m1 is Ga_{1-y5}In_{y5}As alloy, with y5 being the molar fraction of In in the Ga_{1-y5}In_{y5}As alloy, such that 0.46≤y≤0.6; the second material m2 is Inₓ₆Ga₁₋ₓ₆As_{1-y6}P_{y6} alloy, with x6 being the molar fraction of Ga in the Inₓ₆Ga₁₋ₓ₆As_{1-y6}P_{y6} alloy, such that 0.55≤x6≤0.85 and y6 being the molar fraction of P in the Inₓ₆Ga₁₋ₓ₆As_{1-y6}P_{y6} alloy, such that y6=2.x5-z, with 1.13≤z≤1.37. The absorption heterostructure SPA is achieved by epitaxial growth on the substrate SUB.

By way of non-limiting example of the first embodiment of the invention, the substrate SUB is made of InP; the first material m1 is Gaₓ₇In₁₋ₓ₇As_{1-y7}Sb_{y7} alloy, with x7 being the molar fraction of Ga in the Gaₓ₇In₁₋ₓ₇As_{1-y7}Sb_{y7} alloy, such that 0≤x7≤0.3 and with y7 being the molar fraction of Sb in the Gaₓ₇In₁₋ₓ₇As_{1-y7}Sb_{y7} alloy, such that y7=−0.9.x7+z, with 0.46≤z≤0.5; the second material m2 is the Gaₓ₈In₁₋ₓ₈As_{1-y8}Sb_{y8} alloy, with x8 being the molar fraction of Ga in the Gaₓ₈In₁₋ₓ₈As_{1-y8}Sb_{y8} alloy, such that 0≤x8≤0.3 and with y8 being the molar fraction of Sb in the Gaₓ₈In₁₋ₓ₈As_{1-y8}Sb_{y8} alloy, such that y8=−0.9.x8+z, with 0.46≤z≤0.5. The molar fraction x7 of Ga in the Gaₓ₇In₁₋ₓ₇As_{1-y7}Sb_{y7} alloy of the first material m1 is different from the molar fraction x8 of Ga in the Gaₓ₈In₁₋ₓ₈As_{1-y8}Sb_{y8} alloy of the second material m2. The molar fraction y7 of Sb in the Gaₓ₇In₁₋ₓ₇As_{1-y7}Sb_{y7} alloy of the first material m1 is different from the molar fraction y8 of Sb in the Gaₓ₈In₁₋ₓ₈As_{1-y8}Sb_{y8} alloy of the second material m2. The absorption heterostructure SPA is achieved by epitaxial growth on the substrate SUB.

By way of non-limiting example of the first embodiment of the invention, the substrate SUB is made of GaAs; the first material m1 is In₁₋ₓ₉Gaₓ₉As_{1-y9}P_{y9} alloy, with x9 being the molar fraction of Ga in the In₁₋ₓ₉Gaₓ₉As_{1-y9}P_{y9} alloy, such that 0≤x9≤0.3 and y9 being the molar fraction of P in the In₁₋ₓ₉Gaₓ₉As_{1-y9}P_{y9} alloy, such that y9=0.2.x9+z, with 0≤z≤0.05; the second material m2 is the Ga₁₋ₓ₁₀Inₓ₁₀As alloy, with x10 being the molar fraction of In in the Ga₁₋ₓ₁₀Inₓ₁₀As alloy, such that 0≤x10≤0.03. The absorption heterostructure SPA is achieved by epitaxial growth on the substrate SUB.

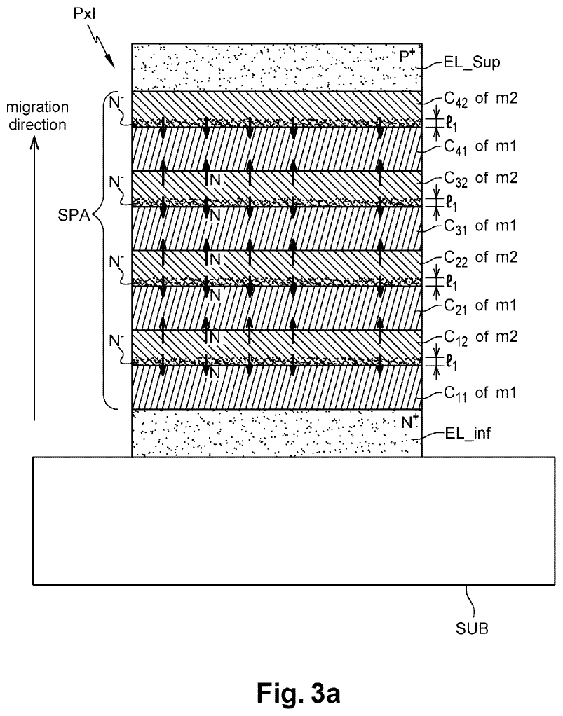

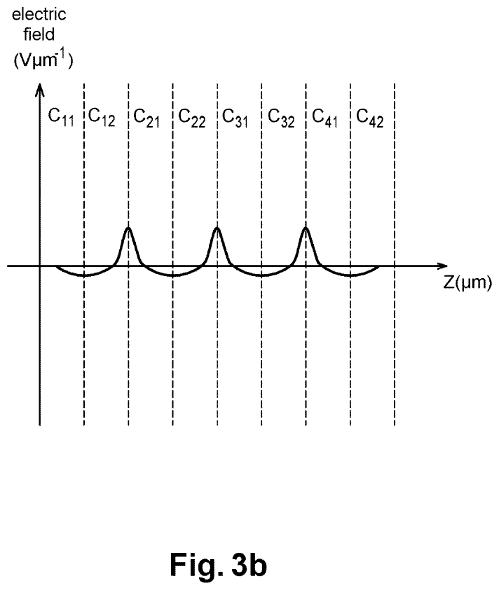

FIG. 3a illustrates a sectional view of an infrared detector pixel Pxl comprising an absorption heterostructure SPA according to a second embodiment of the invention. The absorption heterostructure SPA assumes the structural features described in the first embodiment. The difference between the first embodiment and the second embodiment consists in the distribution of the doping profile of the planar absorption structures Cai and Cᵢ₂, with i=1 to N.

An example will be considered where the minority charge carriers are holes. Thus, all the stacked layers of the absorption heterostructure SPA are N-doped, according to a first predetermined concentration of impurities. It has been established that when the holes transition from a planar structure made of the first material m1 to an adjacent planar structure made of the second material m2 in the migration direction, the holes experience a negative interface electric field E. In this embodiment, at each interface with a negative electric field E, doping asymmetry is integrated on either side of said interface. More specifically, the second planar absorption structure made of the second material m2 has an N⁻ interface doping zone that extends from said interface towards the volume of said second planar absorption structure made of the second material m1. The N⁻ interface doping zone has a second concentration of impurities lower than the first predetermined concentration of impurities. By way of example, each N⁻ interface doping zone is doped with a concentration of 2.10¹⁴ cm⁻³ and the remainder of the volume of the absorption heterostructure SPA is N-doped with a concentration of 1.10¹⁵ cm⁻³. The N⁻ interface doping zone has a penetration depth I1 into the volume of the second planar absorption structure of more than 10 nm.

Doping asymmetry is thus achieved at the interfaces with interface electric fields that slow down the movement of the charge carriers towards the upper collection electrode EL_SUP. The doping asymmetry at the interfaces allows the amplitude of the negative interface electric fields E to be reduced and thus improves the mobility of the photogenerated charges along the axis of the pixel Pxl. FIG. 3b illustrates the distribution of the electric field in the absorption heterostructure SPA in the direction of the axis of the pixel Pxl with the doping asymmetry described above.

Alternatively, the N-type doping profile of the absorption heterostructure SPA has a decreasing gradient from the lower electrode EL_INF towards the upper electrode EL_SUP. This allows more intense interface electric fields E to be provided at of the base of the pixel Pxl relative to the apex next to the upper electrode EL_SUP. Thus, the channelling effect according to the invention is accentuated at the base of the pixel Pxl where the risk of cross-talk is greater.

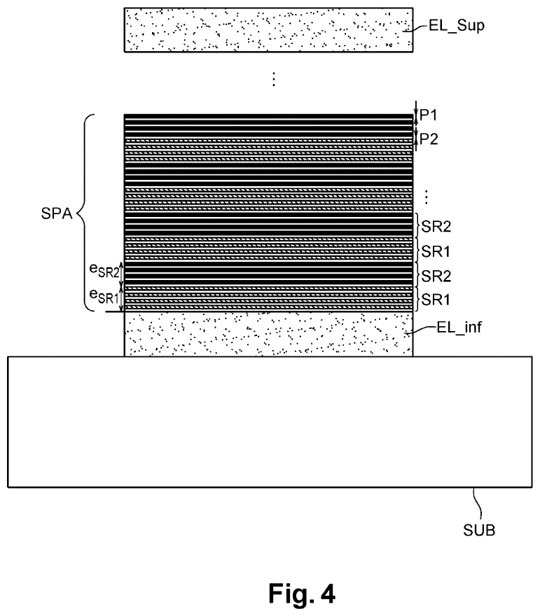

FIG. 4 illustrates a sectional view of an infrared detector pixel Pxl comprising an absorption heterostructure SPA according to a third embodiment of the invention. The absorption heterostructure SPA comprises a first group of N planar absorption structures. Each structure of the first group is produced by a first superlattice SR₁, with N being a non-zero natural integer. The absorption heterostructure SPA further comprises a second group of N planar absorption structures. Each structure of the second group is produced by a second superlattice SR₂, with N being a non-zero natural integer. The superlattices SR₁ and SR₂ are stacked alternately in order to obtain a heterostructure formed by different adjacent superlattices. By way of a reminder, the invention discloses an alternating stack of at least two different superlattices. It is not a single superlattice. The first superlattice SR₁ is characterized by a first maximum valence band value Ev₁, a first minimum conduction band value Ec₁, and a first energy gap value E_{g1}. The second superlattice SR₂ is characterized by a second maximum valence band value Ev₂, a second minimum conduction band value Ec₂, and a second energy gap value E_{g2}. The second maximum valence band value Ev₂ is distinct from the first maximum valence band value Ev₁ with an energy difference (also called offset) of less than 4·K_{b}T, with K_{b} being the Boltzmann constant and τ being the operating temperature of the detector. The level offset of the valence bands induces the creation of a local electric field E at each interface between a planar absorption structure produced by the first superlattice SR₁ and a planar absorption structure produced by the second superlattice SR₂. The same alternating energy band diagram as described in the first embodiment is thus obtained, allowing the charge carriers to be channelled along the axis Δ of the pixel and thus reducing the cross-talk phenomenon between adjacent pixels.

The first superlattice SR₁ and the second superlattice SR₂ are made of semiconductor materials that are preferably of the III-V type. In this embodiment, the absorption zone SPA is an alternating stack of at least two different superlattices, which does not correspond to a superlattice as such.

In general, the design choices of a superlattice according to the invention cover the selection of materials used (materials engineering), the thickness of the layers making up a superlattice, the period of the superlattice (in this case, p₁ and p₂) and the molar fractions when alloys are used. According to a particular aspect of the invention, the second superlattice SR₂ is made up of a stack of layers made of materials different from those that form the first superlattice SR₁. Alternatively, the second superlattice SR₂ is made up of a stack of layers of the same materials as those forming the first superlattice SR₁, but with different layer thicknesses. Alternatively, the second superlattice SR₂ is made up of a stack of layers of the same materials as those forming the first superlattice SR₁, but with different periods p₁≠p₂. Alternatively, the second superlattice SR₂ is made up of a stack of layers of the same alloys as those forming the first superlattice SR₁, but with different molar fractions, layers with different thicknesses and different periods p₁≠p₂.

By way of non-limiting example of the third embodiment of the invention, the substrate SUB is made of GaSb. The first superlattice SR₁ is InAs_{1-y11}Sb_{y11}/Gaₓ₁₂In₁₋ₓ₁₂As_{1-y12}Sb_{y12}, with 0.084≤y11≤0.4 for the ternary alloy and the composition range for the quaternary alloy is a quadrilateral, such that 0.1≤x12≤0.5 and x12=0.1: 0≤y12≤0.25 and x12=0.5: 0.2≤y12≤0.4. The thicknesses of the ternary e_{InAsSb} and of the quaternary e_{GaInAsSb} range between 0.9 nm≤e_{InAsSb}≤2 nm and 0.9 nm≤e_{GaInAsSb} 55 nm. The second superlattice SR₂ is InAs_{1-y′11}Sb_{y′11}/Ga_{x′12}In_{1-x′12}As_{1-y′12}Sb_{y′12}, with 0.084≤y′11≤0.4 for the ternary alloy and the composition range for the quaternary alloy is a quadrilateral, such that 0.1≤x′12≤0.5 and x′12=0.1: 0≤y′12≤0.25 and x′12=0.5: 0.2≤y′12≤0.4. The thicknesses of the ternary e_{InAsSb} and of the quaternary e′GaInAsSb range between 0.9 nm≤e′I_{nAsSb}≤2 nm and 0.9 nm≤e′_{GaInAsSb}≤5 nm. The second superlattice SR₂ has a period p₂ different from the period p₁ of the first lattice SR₁ and/or molar fractions of alloys different from the molar fractions of the alloys forming the first superlattice SR₁. The absorption heterostructure SPA is achieved by epitaxial growth on the substrate SUB.

By way of non-limiting example of the third embodiment of the invention, the substrate SUB is made of InAs. The first superlattice SR₁ is InAs_{1-y13}Sb_{y13}/Gaₓ₁₄In₁₋ₓ₁₄As_{1-y14}Sb_{y14}, with 0≤y13≤0.4 for the ternary alloy and the composition range for the quaternary alloy is a quadrilateral, such that 0.1≤x14≤0.5 and x14=0.1: 0≤y14≤0.25 and x14=0.5: 0.15≤y14≤0.4. The thicknesses of the ternary e_{InAsSb} and of the quaternary e_{GaInAsSb} range between 0.9 nm≤_{eInAsSb≤}2 nm and 0.9 nm≤e_{GaInAsSb}≤5 nm. The second superlattice SR₂ is InAs_{1-y′13}Sb_{y′13}/Ga_{x′14}In_{1-x′14}As_{1-y′14}Sb_{y′14}, with 0≤y′13≤0.4 for the ternary alloy and the composition range for the quaternary alloy is a quadrilateral, such that 0.1≤x′14≤0.5 and x′14=0.1: 0≤y′14≤0.25 and x′14=0.5: 0.1≤y′14≤0.4. The thicknesses of the ternary e_{InAsSb} and of the quaternary e′_{GaInAsSb} range between 0.9 nm≤e′_{InAsSb}≤2 nm and 0.9 nm≤e′_{GaInAsSb}≤5 nm. The second superlattice SR₂ has a period p₂ different from the period p₁ of the first lattice SR₁ and/or molar fractions of alloys different from the molar fractions of the alloys forming the first superlattice SR₁. The absorption heterostructure SPA is achieved by epitaxial growth on the substrate SUB.

By way of non-limiting example of the third embodiment of the invention, the substrate SUB is made of InP. The first superlattice SR₁ is Inₓ₁₅Ga₁₋ₓ₁₅As/Inₓ₁₆Ga₁₋ₓ₁₆As_{1-y16}P_{y16}, with 0.45≤x15≤0.8 for the ternary alloy and the composition range for the quaternary alloy is a quadrilateral, such that 0.4≤x16≤0.8 and x16=0.4: 0≤y16≤0.2 and x16=0.8: 0.55≤y16≤1. The thicknesses of the ternary e_{InGaAs} and of the quaternary e_{InGaAsP} range between 0.9 nm≤e_{InGaAs}≤5 nm and 0.9 nm≤e_{InGaAsP}≤5 nm. The second superlattice SR₂ is In_{x′15}Ga_{1-x′15}As/In_{x′16}Ga_{1-x′16}As_{1-y′16}P_{y′16}, with 0.45≤x′15≤0.8 for the ternary alloy and the composition range for the quaternary alloy is a quadrilateral, such that 0.4≤x′16≤0.8 and x′16=0.4: 0≤y′16≤0.2 and x′16=0.8: 0.55≤y′16≤1. The thicknesses of the ternary e′_{InGaAs} and of the quaternary e′_{InGaAsP} range between 0.9 nm≤e′_{InGaAs}≤5 nm and 0.9 nm≤e′_{InGaAsP}≤5 nm. The second superlattice SR₂ has a period p₂ different from the period p₁ of the first lattice SR₁ and/or molar fractions of alloys different from the molar fractions of the alloys forming the first superlattice SR₁. The absorption heterostructure SPA is achieved by epitaxial growth on the substrate SUB.

By way of non-limiting example of the third embodiment of the invention, the substrate SUB is made of InP. The first superlattice SR₁ is Inₓ₁₇Ga₁₋ₓ₁₇As_{1-y17}Sb_{y17}/Inₓ₁₈Ga₁₋ₓ₁₈As_{1-y18}Sb_{y18} and the second superlattice SR₂ is made of the same materials but with a different period and/or different stoichiometric coefficients.

By way of non-limiting example of the third embodiment of the invention, the substrate SUB is made of GaAs. The first superlattice SR₁ is Inₓ₁₉Ga₁₋ₓ₁₉As/Inₓ₂₀Ga₁₋ₓ₂₀As_{1-y20}P_{y20}, with 0≤x19≤0.2 for the ternary alloy and the composition range for the quaternary alloy is a quadrilateral, such that 0≤x20≤0.3 and x20=0: 0≤y20≤0.4 and x20=0.3: 0.6≤y′20≤1. The thicknesses of the ternary e′_{InGaAs} and of the quaternary e′_{InGaAsP} range between 0.9 nm≤e′_{InGaAs}≤5 nm and 0.9 nm≤e′_{InGaAsP}≤5 nm. The second superlattice SR₂ is In_{x′19}Ga_{1-x′19}As/In_{x′20}Ga_{1-x′20}As_{1-y′20}P_{y′20}, with 0≤x′19≤0.2 for the ternary alloy and the composition range for the quaternary alloy is a quadrilateral, such that 0≤x′20≤0.3 and x′20=0: 0≤y′20≤0.4 and x′20=0.3: 0.6≤y′20≤1. The thicknesses of the ternary e′_{InGaAs} and of the quaternary e′_{InGaAsP} range between 0.9 nm≤e′_{InGaAs}≤5 nm and 0.9 nm≤e′_{InGaAsP}≤5 nm. The second superlattice SR₂ has a period p₂ different from the period p₁ of the first lattice SR₁ and/or molar fractions of alloys different from the molar fractions of the alloys forming the first superlattice SR₁. The absorption heterostructure SPA is achieved by epitaxial growth on the substrate SUB.

Alternatively, an absorption heterostructure SPA according to the invention can be produced in which the alternating energy diagram is obtained by alternately stacking solid layers with superlattices. This is a hybrid embodiment between the first embodiment and the third embodiment.

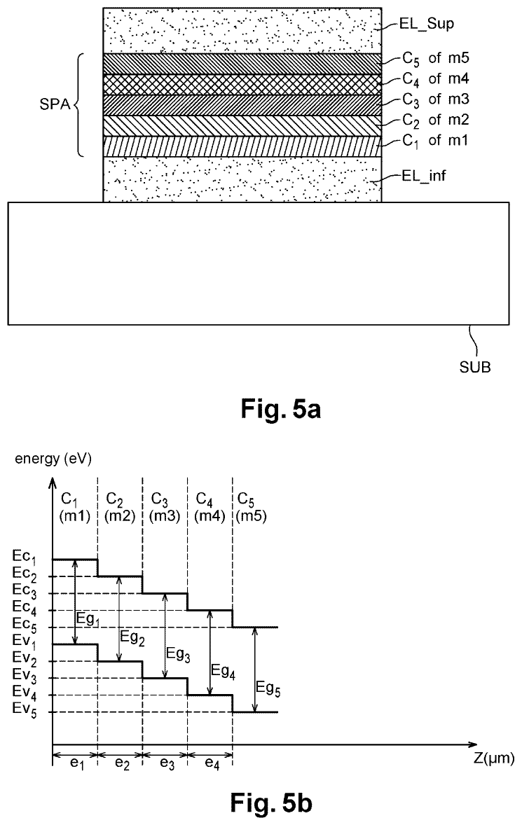

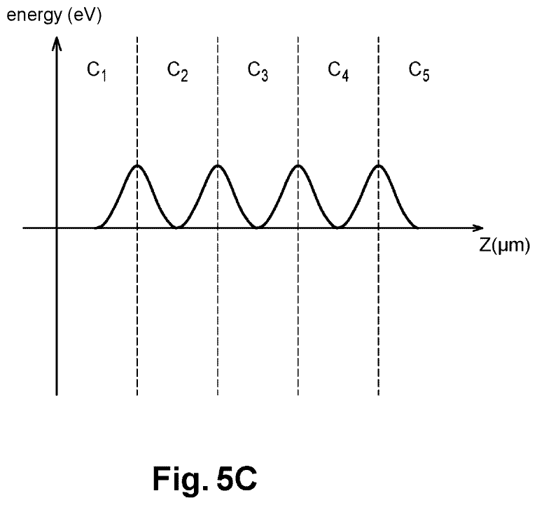

FIG. 5a illustrates a sectional view of an infrared detector pixel Pxl comprising an absorption heterostructure SPA according to a fourth embodiment of the invention. The absorption heterostructure SPA comprises a stack of a plurality of planar structures Cᵢ of rank i=1 to N, with N being a natural integer greater than or equal to 2. The first planar structure C₁ is made of a layer of a first solid material m1 or of a first superlattice SR₁. The second planar structure C₂ is made of a layer of a second solid material m2 or of a second superlattice SR₂, and so on. In the migration direction of minority charge carriers, each planar absorption structure Cᵢ of rank i=1 to N-1 has a maximum valence band value Ev₁ strictly greater than the maximum valence band value Evᵢ₊₁ of the planar absorption structure Cᵢ₊₁ of rank i+1, with an energy difference of less than four times the product of the Boltzmann constant and the operating temperature. A descending stepped energy diagram starting from the lower electrode EL_INF towards the upper electrode EL_SUP is obtained. The absolute difference between the energy gap Egᵢ of the planar absorption structure Cᵢ of rank i=1 to N-1 and the planar absorption structure Cᵢ₊₁ is less than or equal to 20 meV.

Advantageously, each planar absorption structure Cᵢ of rank i=1 to N-1 has a minimum conduction band value Ec₁ strictly greater than the minimum conduction band value Ecᵢ₊₁ of the planar absorption structure of rank i+1, with an energy difference of less than four times the product of the Boltzmann constant and the operating temperature.

A succession of several layers Cᵢ of rank i=1 to N is thus obtained, starting from EL_INF in the first direction Z with a diagram of energy bands in the form of descending steps. FIG. 5b illustrates a diagram of the structure of the bands of the absorption heterostructure SPA according to the fourth embodiment of the invention in the direction of the axis of the pixel Pxl.

The materials used to produce the absorption heterostructure are semiconductor materials, preferably of the III-V type.

The selection of valence and conduction levels for the planar absorption structures Cᵢ allows an energy diagram in the form of descending steps to be obtained. Each energy step corresponds to the interface between two planar absorption structures. Each energy difference at the interface induces an interface electric field E directed along Z, the direction of the axis Δ of the pixel Pxl.

The advantage of this embodiment is that the energy variation is always in the same direction, allowing positive interface electric fields E to be induced, as illustrated in FIG. 5c. The direction of E is thus always identical to the migration direction of the minority charge carriers.

By way of non-limiting example of the fourth embodiment of the invention, the absorption heterostructure SPA comprises the following series of superlattices SRᵢ stacked in this order InAs_{1-yi}Sb_{yi}/GaₓIn₁₋ₓAs_{1-y′i}Sb_{y′i}, with i=[1,2,3,4] and 0.2≤x≤0.5 and such that 0.7≤y1,y1′≤0.8 and 0.65≤y2,y2′≤0.75 and 0.6≤y3,y3′≤0.7 and 0.55≤y4,y4′≤0.65.

1. A detection device (D1) configured to detect infrared radiation at a predetermined operating temperature, comprising at least one pixel (Pxl) formed by a stack of layers on a substrate (SUB) in the first direction (Z) normal to said substrate (SUB), said pixel comprising an absorption heterostructure (SPA), said absorption heterostructure (SPA) comprising at least:
a first planar absorption structure (C₁₁, SR₁) having a first maximum valence band value (Ev₁);
and a second planar absorption structure (C₁₂, SR₂) adjacent to the first planar absorption structure (C₁₁, SR₁);
said second planar absorption structure (C₁₂, SR₂) having a second maximum valence band value (Ev₂) distinct from the first maximum valence band value (Ev₁); the thickness (e₁₁, e₁₂, e_{SR1}, e_{SR2}) of each of the first and second planar absorption structures (C₁₁, SR₁, C₁₂, SR₂) being greater than or equal to 20 nm;
the thickness (e₁₁, e₁₂, e_{SR1}, e_{SR2}) of each of the first and second planar absorption structures being selected so as to create at least one interface electric field (E) at the interface between the second planar absorption structure (C₁₂, SR₂) and the first planar absorption structure (C₁₁, SR₁), said interface electric field (E) being oriented in said first direction (Z).

2. The detection device (D1) according to claim 1, wherein the difference between the first maximum valence band value (Ev₁) and the second maximum valence band value (Ev₂) is less than four times the product of the Boltzmann constant and the operating temperature.

3. The detection device (D1) according to claim 1, wherein the first planar absorption structure (C₁₁, SR₁) has a first energy gap (Eg₁) and the second planar absorption structure (C₁₁, SR₁) has a second energy gap (Eg₂), with the absolute difference between the first energy gap (Eg₁) and the second energy gap (Eg₂) being less than or equal to 20 meV.

4. The detection device (D1) according to claim 1, wherein the first planar absorption structure (C₁₁, SR₁) has a first minimum conduction band value (Ec₁) and the second planar absorption structure (C₁₂, SR₂) has a second minimum conduction band value (Ec₂) distinct from the first minimum conduction band value (Ec₁) with an energy difference of less than four times the product of the Boltzmann constant and the operating temperature.

5. The detection device (D1) according to claim 1, wherein the absorption heterostructure (SPA) comprises a periodic alternation of the first planar absorption structure (C₁₁, SR₁) and the second planar absorption structure (C₂₁, SR₂).

6. The detection device (D1) according to claim 1, wherein the absorption heterostructure (SPA) is doped with N- or P-type dopants, with the concentration of said dopants being asymmetrical on either side of at least one interface between a first planar absorption structure (C₁₁, SR₁) and a second planar absorption structure (C₁₂, SR₂).

7. The detection device (D1) according to claim 1, said pixel (Pxl) comprises, starting from the substrate, in the first direction (Z): a lower electrode (EL_INF), the absorption zone (SPA) and an upper electrode (EL_SUP); the absorption heterostructure (SPA) being doped with N- or P-type dopants, with the concentration of said dopants having a decreasing gradient from the interface with the lower electrode to the interface with the upper electrode.

8. The detection device (D1) according to claim 1, wherein the absorption zone (SPA) comprises a stack of a succession of several planar absorption structures (C₁, C₂, C₃, C₄, C₅) of rank i=1 to N increasing from the substrate (SUB) in the first direction (Z), with N being a natural integer strictly greater than 1, such that:
each planar absorption structure (C₁, C₂, C₃, C₄) of rank i=1 to N-1 has a maximum valence band value (Ev₁) that is strictly greater than the maximum valence band value of the planar absorption structure (Ev₁+1) of rank i+1, so as to create at least one interface electric field (E) directed in the first direction (Z) at each interface;
with said succession of several planar absorption structures (C₁, C₂, C₃, C₄, C₅) comprising the assembly formed by the first planar absorption structure (C₁₁, SR₁) and the second planar absorption structure (C₁₂, SR₂).

9. The detection device (D1) according to claim 8, wherein the difference between, on the one hand, the maximum valence band value (Ev₁) of a planar absorption structure (C₁, C₂, C₃, C₄) of rank i=1 to N-1 and, on the other hand, the maximum valence band value (Ev₁) of an adjacent planar absorption structure (C₂, C₃, C₄, C₅) of rank i+1 is less than four times the product of the Boltzmann constant and the operating temperature.

10. The detection device (D1) according to claim 8, wherein the absolute difference between the energy gaps associated with two adjacent planar absorption structures (C₁, C₂, C₃, C₄, C₅) is less than or equal to 20 meV.

11. The detection device (D1) according to claim 1, wherein each planar absorption structure is made of III-V type semiconductor materials.

12. The detection device (D1) according to claim 1, wherein the substrate is made of GaSb or InAs or InP or GaAs.

13. The detection n device (D1) according to claim 1, wherein:
the first planar absorption structure (C₁₁, SR₁) is produced by a first solid layer (C₁₁) made of a first material (m1) or a first superlattice (SR₁);
the second planar absorption structure (C₁₁, SR₁) is produced by a second solid layer (C₁₂) made of a second material (m2) different from said first material or a second superlattice (SR₂).

14. The detection device (D1) according to claim 13, wherein the first material (m1) is InAs_{1-y}Sb_{y} alloy or Ga₁₋ₓInₓAs alloy or GaxIn₁₋ₓAs_{1-y}Sb_{y} alloy or GaₓIn₁₋ₓAs_{1-y}P_{y} alloy.

15. The detection device (D1) according to claim 13, wherein the second material (m2) is GaₓIn₁₋ₓAs_{1-y}Sb_{y} alloy or Ga₁₋ₓInₓAs alloy or GaₓIn₁₋ₓAs_{1-y}P_{y} alloy.

16. The detection device (D1) according to claim 15, wherein the first superlattice and/or the second superlattice is formed by an alternation in accordance with a predetermined spatial period (p₁, p₂) of a pair of layers of InAs_{1-y}Sb_{y}/GaxIn₁₋ₓAs_{1-y}Sb_{y};
or of InₓGa₁₋ₓAs/InₓGa₁₋ₓAs_{1-y}P_{Py};
or of Inₓ₁Ga₁₋ₓ₁As_{1-y1}Sb_{y1}/Inₓ₂Ga₁₋ₓ₂As_{1-y2}Sb_{y2}.

17. The detection device (D1) according to claim 1, comprising a pixel matrix (Pxl) having a pixel pitch that is less than or equal to 15 μm.
